(19) United States
(12) Patent Application Publication
(10) Pub. No.: US 2006/0040502 A1
(43) Pub. Date: Feb. 23, 2006

(54) Method for manufacturing semiconductor device

(76) Inventors: Hiroyuki Fukumizu, Kawasaki-shi (JP); Shingo Honda, Yokkaichi-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/206,153

(22) Filed: Aug. 18, 2005

(30) Foreign Application Priority Data
Aug. 18, 2004 (JP) 2004-238581
Jun. 20, 2005 (JP) 2005-179313

(51) Int. Cl. H01L 21/302

(52) U.S. Cl. 438/706; 438/710; 438/700; 438/717

(57) ABSTRACT

A wiring material film is formed by depositing a first conductive barrier film, an aluminum film, and a second conductive barrier film on a semiconductor substrate in this order. An organic material film, a silicon oxide film and a resist film are formed on the surface of the second barrier film in this order. A resist pattern is formed on silicon oxide film. A pattern of the silicon oxide film is formed on the surface of the organic material film by etching the silicon oxide film with a process gas containing at least fluorine using the resist pattern as a mask. The substrate is treated with a plasma of a process gas containing C before exposing the substrate to air after forming the pattern of the organic material film on the surface of the conductive barrier film by etching the organic material film.

### CROSS-REFERENCE TO RELATED APPLICATIONS

This application is based upon and claims the benefit of priority from prior Japanese Patent Applications No. 2004-238581, filed Aug. 18, 2004; and No. 2005-179313, filed Jun. 20, 2005, the entire contents of both of which are incorporated herein by reference.

### BACKGROUND OF THE INVENTION

1. Field of the Invention

The invention relates to a method for manufacturing a semiconductor device.

2. Description of the Related Art

The thickness of a resist pattern that can be processed by lithography tends to be reduced in a process of manufacturing a semiconductor device in accordance with miniaturization of elements. When a wiring material film having, for example, a three-layer structure comprising a TiN film (a first conductive barrier film), an aluminum film and a TiN film (a second conductive barrier film) on a semiconductor substrate is processed using such a thin resist pattern as a mask, the thickness of the resist pattern required for the mask is insufficient. Consequently, it is difficult to form a highly accurate wiring pattern with good reproducibility.

Based on the situation as described above, Jpn. Pat. Appln. KOKAI Publication No. 2000-182998 discloses a multilayer resist method as described below. First, a relatively thick organic material film, a silicone oxide film and a thin resist film are formed on the second conductive barrier layer of the wiring material film in this order. The uppermost resist is formed into a resist pattern by a lithographic technique. Subsequently, a pattern of the silicon oxide film is formed by etching (for example, reactive ion etching: RIE) with a process gas containing fluorine, for example a CF₄/O₂ gas, using the resist pattern as a mask. Subsequently, a relatively thick pattern of the organic material film is formed by RIE with a process gas containing N and H, for example, a process gas containing NH₃, using the pattern of the silicon oxide film as a mask.

The semiconductor substrate having the wiring material film on which the pattern of the organic material film has been formed is transferred from an RIE apparatus for forming the pattern of the organic material film to another RIE apparatus, and a wiring layer is formed by RIE processing of the wiring material film using the pattern of the organic material film as a mask. In other words, the semiconductor substrate is exposed to air during transfer to another RIE apparatus. However, when the wiring material film on which the pattern of the organic material film is formed is exposed to air, a corroded layer is formed due to fluorine at a portion of the second conductive barrier film (for example a TiN film) of the wiring material film exposed in the vicinity of the pattern of the organic material film as a mask material. Such a corroded layer serves as an unnecessary etching mask when the wiring material film is processed by RIE by taking advantage of the mask material described above. Accordingly, it is difficult to form a wiring that accurately reflects the pattern of the mask material formed by the multilayer resist method.

### BRIEF SUMMARY OF THE INVENTION

According to one aspect of the present invention, there is provided a method for manufacturing a semiconductor device, comprising:

forming a wiring material film of a stacked structure by depositing a first conductive barrier film, an aluminum film or an aluminum alloy film, and a second conductive barrier film on a semiconductor substrate in this order;

an organic material film, a silicon oxide film and a resist film on the surface of the second barrier film in this order;

a resist pattern on the surface of the silicon oxide film by patterning the resist film by lithography;

a pattern of the silicon oxide film on the surface of the organic material film by etching the silicon oxide film with a process gas containing at least fluorine using the resist pattern as a mask;

treating the substrate with a plasma of a process gas containing C, a process gas containing H or a process gas containing O before exposing the substrate to air after forming the pattern of the organic material film on the surface of the conductive barrier film by etching the organic material film with a process gas containing H and N using the pattern of the silicon oxide film as a mask; and

forming a wiring by etching the wiring material film using the patterns of the silicon oxide film and organic material film as masks.

According to another aspect of the present invention, there is provided a method for manufacturing a semiconductor device, comprising:

forming a wiring material film of a stacked structure by depositing a first conductive barrier film, an aluminum film or an aluminum alloy film and a second conductive barrier film on a semiconductor substrate in this order;

forming an organic material film, a silicon oxide film and a resist film on the surface of the second conductive barrier film in this order;

forming a resist pattern on the surface of the silicon oxide film by patterning the resist film by lithography;

forming a pattern of the silicon oxide film on the surface of the organic material film by etching the silicon oxide film with a process gas containing at least fluorine using the resist pattern as a mask;

providing a plasma etching apparatus comprising a vacuum chamber and two plate electrodes arranged in the vacuum chamber so as to parallel each other;

holding the semiconductor substrate having the pattern of the silicon oxide film on one plate electrode in the vacuum chamber of the plasma etching apparatus;

introducing a process gas containing O in the vacuum chamber;

adjusting the pressure in the chamber to 1 Pa or less;

generating an oxygen plasma in the chamber by applying a high frequency power to the other plate electrode to selectively etch the organic material film using the pattern of the silicon oxide film as a mask, thereby forming a pattern of the organic material film on the surface of the conductive barrier film; and

forming a wiring by etching the wiring material film using the patterns of the silicon oxide film and organic material film as masks.

### BRIEF DESCRIPTION OF THE SEVERAL VIEWS OF THE DRAWING

FIGS. 1A, 1B, 1C, 1D and 1E are cross sections showing a process of manufacturing a semiconductor device in Example 1 of the invention;

FIG. 2 shows an SEM photograph of a wiring material film including layered patterns of an SOG film and a novolac resin film before transfer to a lower electrode in a chamber of an RIE apparatus of an ICP type after taking out of an RIE apparatus of a parallel plate type into air in a process of manufacturing a semiconductor device in Comparative Example 1;

FIG. 3 shows an SEM photograph of a wiring material film including layered patterns of an SOG film and a novolac resin film before transfer to a lower electrode in a chamber of an RIE apparatus of an ICP type after taking out of an RIE apparatus of a parallel plate type into air in the process of manufacturing a semiconductor device in Example 1;

FIG. 4 shows an SEM photograph of a wiring material film including layered patterns of an SOG film and a novolac resin film before transfer to a lower electrode in a chamber of an RIE apparatus of an ICP type after taking out of an RIE apparatus of a parallel plate type into air in a process of manufacturing a semiconductor device in Example 2;

FIG. 5 is a schematic cross section showing a plasma etching apparatus of a parallel plate type for use in forming a pattern of an organic material film (a pattern of a novolac resin film) in Example 3; and

FIG. 6 is an SEM photograph of a wiring material film having a two-layer pattern comprising the patterns of the SOG film and novolac resin film immediately after forming the pattern of the novolac resin film using an RIE apparatus of a parallel plate type in the process of manufacturing a semiconductor device in Example 3.

### DETAILED DESCRIPTION OF THE INVENTION

A method for manufacturing a semiconductor device according to the invention will be described in detail hereinafter.

### First Embodiment

A first embodiment will be described with reference to the first to fourth steps.

(First Step)

A stacked structure of a wiring material film is formed by depositing a first conductive barrier film, an aluminum film or an aluminum alloy film, and a second conductive barrier film on a semiconductor substrate in this order. Subsequently, an organic material film, a silicon oxide film and a resist film are formed on the surface of the second conductive barrier film of the wiring material film.

The wiring material film of the stacked structure is formed, for example, on the surfaces of interlayer dielectric films of the first and second layers and so forth on the semiconductor device.

The first and second conductive barrier layers are used for preventing migration of an aluminum film or an aluminum alloy film located at an intermediate position of these barrier layers. These conductive barrier layers are formed of at least one layer selected from Ti, TiN, Ta, TaN, W and WN films.

Examples of the aluminum alloy include an Al—Si alloy, Al—Cu alloy and Al—Cu—Si alloy.

Examples of the organic material film available include a novolac resin film (trade name PRE IX370G, manufactured by JSR Co.), a coated carbon film and a plasma CVD carbon film.

A spin-on-glass (SOG) film may be used, for example, as the silicon oxide film. The silicon oxide film preferably has a thickness of 30 to 80 nm. A corroded layer ascribed to fluorine can be effectively prevented from being formed at the portion of the wiring material film after forming the pattern of the organic material film, by using the silicon oxide film having the thickness as described above.

Examples of the resist available include a chemical amplification resist (trade name M60G, manufactured by JSR Co.) and a resist comprising naphthoquinone diazide and novolac resin (trade name IX770, manufactured by JSR Co.).

(Second Step)

The resist film is patterned by lithography using, for example, a KrF stepper or an ArF stepper to form a desired resist pattern on the surface of the silicon oxide film. Subsequently, the silicon oxide film is etched with a process gas containing at least fluorine (F) using the resist pattern as a mask to form a silicon oxide pattern on the surface of the organic material film.

Examples of the fluorine-containing process gas available include CHF₃/O₂, CF₄/O₂, C₄F₈/O₂, CHF₃/Ar, CF₄/Ar and C₄F₈/Ar/O₂. For example, a reactive ion etching (RIE) process capable of forming a pattern of silicon oxide that can more accurately reflect the resist pattern is preferably employed for the etching process using the process gas.

(Third Step)

A pattern of an organic material film is formed on the surface of the second conductive barrier film by etching the organic material film with a process gas containing H and N, or with a process gas containing N and O, using the pattern of the silicone oxide film as a mask. The semiconductor substrate having the pattern of the organic material film is treated with a plasma of a process gas containing C, a process gas containing H or a process gas containing O before exposing the substrate in air.

Examples of the process gas containing H and N available include an N₂/H₂ gas, while examples of the process gas containing H, N and C available include an NH₃/O₂ and N₂/CH₄/O₂ gas. A gas containing a low concentration of O₂ (for Example 10% or less) is preferably used as the process gas containing H, N and O. For example, a reactive ion etching (RIE) process capable of forming a pattern of the organic material film that can more accurately reflect the pattern of the silicon oxide is preferably employed in the etching process using this process gas.

Examples of the process gas containing C for use in the plasma treatment include gases of saturated hydrocarbons such as CH₄, C₂H₆ and C₃H₈, and CO; examples of the process gas containing H include hydrogen; and examples of the process gas containing O include oxygen and CO₂. The process gas containing C and H such as a gas of saturated hydrocarbon is preferably used in this plasma treatment.

In this third step, the organic material film is etched with the process gas containing H and N, or with the process gas containing H, N and O using the silicon oxide film as a mask to form the pattern of the organic material film on the surface of the conductive barrier film. Thereafter, the semiconductor substrate having the pattern of the organic material film is treated with a plasma of the process gas containing C (or C and H), the process gas containing H, or the process gas containing C without exposing to air. Consequently, ammonium fluoride that is corrosive to the second conductive barrier layer can be suppressed or prevented from being generated from the process gas containing F and the process gas containing H and N in the presence of moisture in air. This means that corroded layers, which serve as unnecessary etching masks, can be suppressed or prevented from being formed at the portions of the wiring material film exposed out of the pattern of the organic material film. This phenomenon is believed to occur by the following reaction mechanism.

For example, when fluoride and ammonia derived from each process gas are attached to the portions of the wiring material film (the second conductive barrier film) exposed out of the pattern of the organic material film, the portion of the wiring material film having attached substances is coated with a carbon film originating from carbon by applying a plasma treatment of the process gas containing C. Consequently, a strongly corrosive reaction product between ammonium fluoride and water vapor is prevented from being formed at the portion of the wiring material film (the second barrier film) exposed out of the pattern of the organic material film even when the substrate is exposed in air after the plasma treatment, since the carbon film functions as a shielding film against moisture.

When fluoride and ammonia derived from each process gas are attached to the portion of the wiring material film (the second conductive barrier film) exposed out of the pattern of the organic material film, fluoride is converted into hydrogen fluoride having a high vapor pressure and is dissipated by applying a plasma treatment of the process gas containing H. As a result, fluorine in the corrosive ammonium fluoride is removed even by exposing the substrate in air after a plasma treatment from which fluoride sources have been removed.

When fluoride and ammonia derived from respective process gases are attached to the portion of the wiring material film (the second conductive barrier film) exposed out of the pattern of the organic material film, the portion of the second conductive barrier film having attached substances is oxidized and coated with an oxide film by applying a plasma treatment of the process gas containing O. As a result, the oxide film functions as a shielding film against moisture even by exposing the substrate in air after the plasma treatment, and prevents a corrosive substance from being formed by the reaction between ammonium fluoride and water vapor at the portion of the second conductive barrier film exposed out of the pattern of the organic material film.

(Fourth Step)

A wiring is formed by applying etching, for example RIE, to the wiring material film using as a mask a two-layer pattern comprising the pattern of the silicon oxide film and the pattern of the organic material film.

In the etching process in this fourth step, the corroded layer, which serves as an unnecessary etching mask at the portion of the second conductive barrier film exposed out of the pattern of the organic material film, is suppressed or prevented from being formed as described above. Consequently, a wiring that accurately reflects the pattern of the organic material film may be formed.

### Second Embodiment

A second embodiment will be described with reference to the first to fourth steps.

(First Step)

A wiring material film having a stacked structure is formed by depositing a first conductive barrier film, an aluminum film or an aluminum alloy film and a second conductive barrier film on a semiconductor substrate in this order. Subsequently, an organic material film, a silicon oxide film and a resist film are formed on the surface of the second conductive barrier film of the wiring material film in this order.

This first step is the same as the first step in the first embodiment described above. The position for forming the wiring material film having the stacked structure, and materials of the first and second conductive barrier films, the aluminum alloy film, the organic material film, the silicon oxide film and the resist film are also the same as those described in the first embodiment.

(Second Step)

A desired resist pattern is formed on the surface of the silicon oxide film by patterning the resist film by lithography using, for example, a KrF stepper or an ArF stepper. Subsequently, a pattern of the silicon oxide film is formed on the surface of the organic material film by etching the silicon oxide film with a process gas containing at least fluorine using the resist pattern as a mask.

The second step is the same as the second step in the first embodiment described above. A method for forming the resist pattern, a process gas containing fluorine, and a method for forming the pattern of the silicon oxide film using the process gas are also the same as those described in the first embodiment. A reactive ion etching (RIE) process capable of forming a pattern of the silicon oxide film that is able to more precisely reflect the resist pattern is preferably employed in the etching process using the process gas containing fluorine.

(Third Step)

A plasma etching apparatus (for example a reactive ion etching apparatus), which comprising a vacuum chamber and two plate electrodes arranged in the vacuum chamber so as to parallel each other, is provided. The semiconductor substrate having the pattern of the silicon oxide film is placed on the one of plate electrode in the vacuum chamber of the RIE apparatus. Then, the gas in the chamber is evacuated, and a process gas containing O is introduced into the chamber at a pressure of 1 Pa or less in the chamber. A high frequency power with a frequency of higher than 13.56 MHz, for example 100 MHz, is applied to the other parallel electrode in the chamber, thereby generating oxygen plasma in a region between the parallel plate electrodes in the chamber. The organic material film is etched preferably by RIE using the pattern of the silicon oxide film as a mask, and a pattern of the organic material film is formed on the surface of the second conductive barrier film.

An example of the process gas containing O is oxygen.

When the pressure of the oxygen plasma generated in the vacuum chamber exceeds 1 Pa, a pattern of the organic material film that precisely reflects the pattern of the silicon oxide film cannot be formed, because side-etching occurs when the organic material film is etched using the pattern of the silicon oxide film as a mask. The pressure in the chamber is more preferably 0.5 to 1 Pa.

A stable plasma can be generated at a low pressure region of 1 Pa or less that is able to suppress side-etching in the third step, by controlling the pressure in the chamber to 1 Pa or less when the process gas containing O is introduced into the chamber, and by increasing the frequency of the rf power applied to the other plate electrode from 13.56 MHz to, for example, 100 MHz. Accordingly, a pattern of the organic material film that precisely reflects the pattern of the silicon oxide film may be formed in the process of etching the organic material film using the silicon oxide film as a mask. Since a gas containing O such as oxygen is used as the process gas to be introduced in the chamber in the third step, no corroded layer that serves as an unnecessary etching mask is formed at the portion of the wiring material film (the second conductive barrier film) exposed out of the pattern of the organic material film as described in the first embodiment, even by exposing the substrate to air after forming the pattern of the organic material film.

(Fourth Step)

A wiring is formed by subjecting the wiring material film to an etching process, for example RIE process, using the patterns of the silicon oxide film and organic material film as masks.

Since no corroded layer that serves as an unnecessary etching mask is formed at the portion of the wiring material film (the second conductive barrier film) exposed out of the pattern of the organic material film in the etching process in the fourth step as described above, a wiring that precisely reflects the pattern of the organic material film as the mask material may be formed.

Examples of the invention will be described in detail hereinafter with reference to drawings.

### EXAMPLE 1

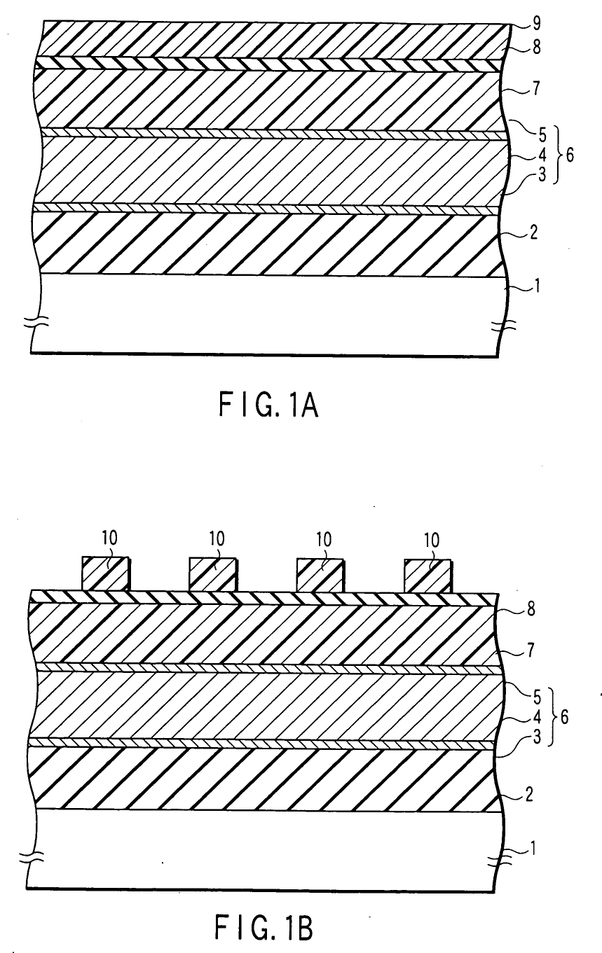

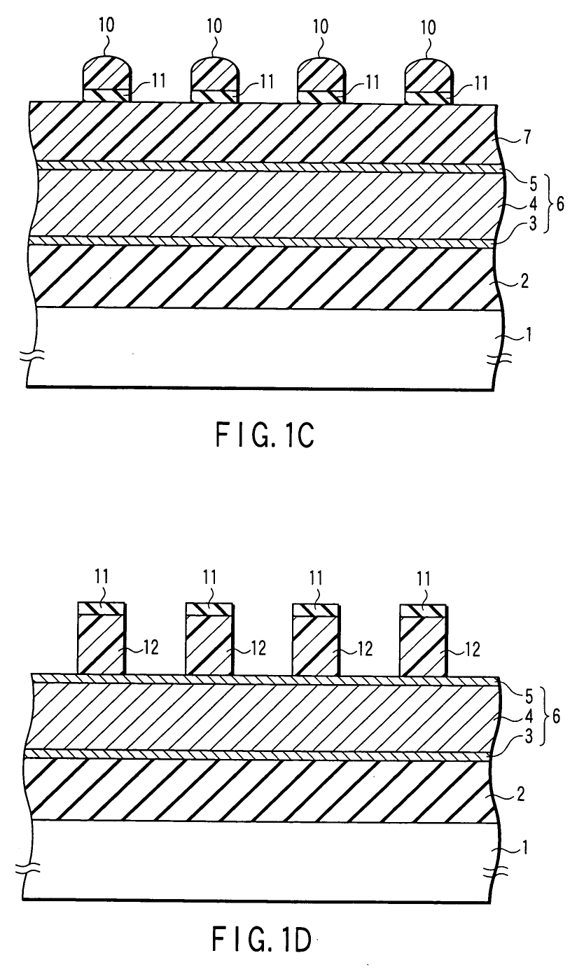

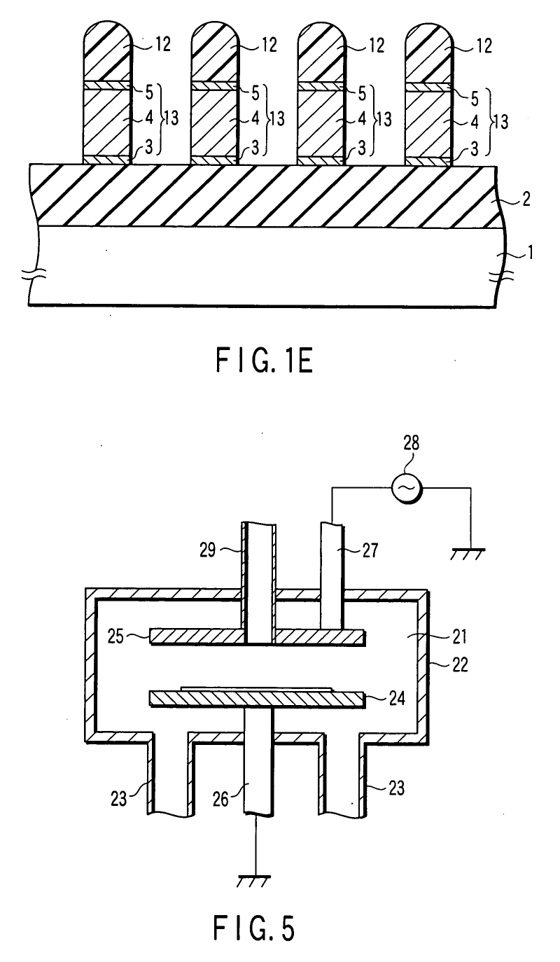

An interlayer dielectric film 2 consisting of SiO₂ was deposited by a CVD method as shown in FIG. 1A on the surface of a silicon substrate 1 as a semiconductor substrate. A wiring material film 6 with a three-layer structure (substantially a five-layer structure) was formed by depositing a first conductive barrier film 3 of titanium/titanium nitride with a thickness of 10 nm and 30 nm, respectively, an Al—Cu alloy film (an aluminum alloy film) 4 with a thickness of 220 nm, and a second conductive barrier film 5 of titanium/titanium nitride with a thickness of 10 nm and 30 nm, respectively, in this order on the surface of the interlayer dielectric film 2 by a sputtering method. Subsequently, a novolac resin film (trade name PER IX370G, manufactured by JSR Co.) 7 with a thickness of 300 nm as an organic material film and an SOG film 8 with a thickness of 80 nm were formed by a spin-coat method in this order on the surface of the second conductive barrier film 5 of the wiring material film 6. A chemical amplification resist (trade name M60G, manufactured by JSR Co.) was further coated on the surface of the SOG film 8 to form a resist film 9 with a thickness of 200 nm after drying.

Subsequently, the resist film 9 is patterned by lithography using a KrF stepper to form a resist pattern 10 with a width of 110 nm on the surface of the SOG film 8 as shown in FIG. 1B. A reactive ion etching (RIE) apparatus, which comprises a vacuum chamber and two plate electrodes arranged in the vacuum chamber so as to parallel each other, was provided. Then, the silicon substrate 1 was transferred onto the lower plate electrode in the chamber of the RIE apparatus. Process gasses CHF₃ and O₂ were supplied into the chamber with flow rates of 100 sccm and 20 sccm, respectively, while the gas in the chamber is evacuated at a reduced pressure of 6 Pa, and then, an RF output of 500 W at a frequency of 13.56 MHz was applied on the lower plate electrode. The SOG film 8 was processed by RIE using the resist pattern 10 as a mask as shown in FIG. 1C to form a pattern 11 of the SOG film.

Another reactive ion etching (RIE) apparatus, which comprises a vacuum chamber and two plate electrodes arranged in the vacuum chamber so as to parallel each other, was provided. Subsequently, the silicon substrate 1 having the pattern 11 of the SOG film was taken out of the chamber of the RIE apparatus into air, and was transferred onto the lower plate electrode in the chamber of another RIE apparatus. Process gasses NH₃ and O₂ were supplied into the chamber with flow rates of 300 sccm and 60 sccm, respectively, while the gas in the chamber of the RIE apparatus is evacuated to a reduced pressure of 6 Pa, and then, an RF output of 500 W at a frequency of 13.56 MHz was applied on the lower plate electrode. The novolac resin film 7 was processed by RIE using the pattern 11 of the SOG film as a mask to form a pattern 12 of the novolac resin. Thereafter, a process gas CH₄ was supplied into the chamber at a flow rate of 100 sccm while the process gas in the chamber of the RIE apparatus is evacuated to a reduced pressure of 3 Pa. Then, the surface portion of the second barrier film 5 exposed out of the pattern 12 of the novolac resin was subjected to CH₄ plasma treatment (see FIG. 1D) by applying an RF output of 500 W at a frequency of 13.56 MHz on the lower plate electrode.

Then, an RIE apparatus of an ICP type, which comprises a vacuum chamber and each of a parallel two plate electrodes arranged in the vacuum chamber, was provided. The silicon substrate 1 having a two-layer pattern comprising the pattern 11 of the SOG film and pattern 12 of the novolac resin film was taken out of the chamber of the RIE apparatus into air, and was transferred onto the lower electrode in the chamber of the RIE apparatus of an ICP type. A process gas containing CHF₃, Cl₂ and BCl₃ was supplied into the chamber while evacuating the gas in the chamber of the RIE apparatus to a predetermined reduced pressure, and an RF output was applied thereafter. The second conductive barrier film 5 of the wiring material film 6 was processed by RIE using the two-layer pattern comprising the pattern 11 of the SOG film and the pattern 12 of the of the novolac resin film as a mask. Subsequently, the process gas containing CH₄, Cl₂ and BCl₃ was supplied into the chamber while evacuating the gas in the chamber to a predetermined reduced pressure, and an RF output was applied thereafter. The Al alloy film 4 of the wiring material film 6 was processed by RIE using the two-layer pattern as a mask. Then, the gas in the chamber was evacuated, and the first conductive barrier film 3 was processed by RIE under the same conditions as those in the RIE process of the second conductive barrier film 5. As a result, a wiring 13 having a stacked structure comprising the first conductive barrier film 3, the Al alloy film 4 and the second conductive barrier film 5 was formed on the surface of the interlayer dielectric film 2 as shown in FIG. 1E. The semiconductor device was thus manufactured.

### COMPARATIVE EXAMPLE 1

A Wiring was formed to manufacture a semiconductor device in the same manner as in Example 1, except that the substrate was taken out of the chamber of the RIE apparatus into air without subjecting it to a CH₄ plasma treatment after forming a pattern of the novolac resin film by an RIE processing of the novolac resin film using the pattern of the SOG film as a mask in the RIE apparatus of the parallel plate type, and the wiring material film was subjected to RIE processing after transferring the substrate onto the lower electrode in the chamber of the RIE apparatus of the ICP type.

In the process of manufacturing the semiconductor device in Example 1 and Comparative Example 1, the silicon substrate having a two-layer pattern comprising the patterns of the SOG film and novolac resin film was taken out of the chamber of the RIE apparatus of the parallel plate type into air. Then, the state of the wiring material film (the TiN film of the second conductive barrier film) having the two-layer pattern comprising the patterns of the SOG film and novolac resin film was observed by means of a scanning electron microscope before transferring the substrate onto the lower electrode in the chamber of the RIE apparatus of the ICP type.

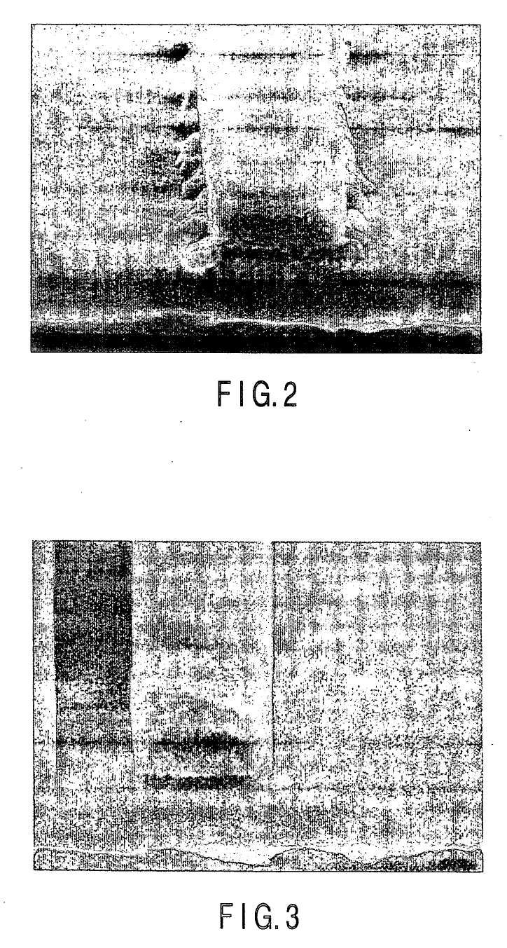

As shown in the SEM photograph in FIG. 2, whiskers of a corroded layer were formed at the TiN film of the second conductive barrier film located in the vicinity of the wall of the two-layer pattern in Comparative Example 1.

On the contrary, whiskers of the corroded layer were not formed at all at the TiN film of the second conductive barrier film located in the vicinity of the wall of the two-layer pattern as shown in the SEM photograph in FIG. 3 of Example 1.

The wiring formed in Comparative Example 1 had a larger width than the width (110 nm) of the original resist pattern, while the wiring formed in Example 1 had an width (110 nm) that precisely reflects the width of the resist pattern. This may be elucidated by the presence or absence of the whiskers of the corroded layer.

### EXAMPLE 2

A wiring was formed by the same method as in Example 1 to manufacture the semiconductor device, except that, as in Example 1, the pattern of the novolac resin was formed by RIE processing of the novolac resin film using the pattern of the SOG film as a mask in the chamber of the RIE apparatus of the parallel plate type, and thereafter, an H₂ plasma treatment was applied to the surface portion of the second conductive barrier film exposed out of the pattern of the novolac resin by supplying the process gas H₂ in the chamber at a flow rate of 200 sccm while the process gas in the chamber of the RIE apparatus is evacuated to a reduced pressure of 4 Pa, and by applying an RF output of 500 W at a frequency of 13.56 MHz for 6 seconds on the lower plate electrode.

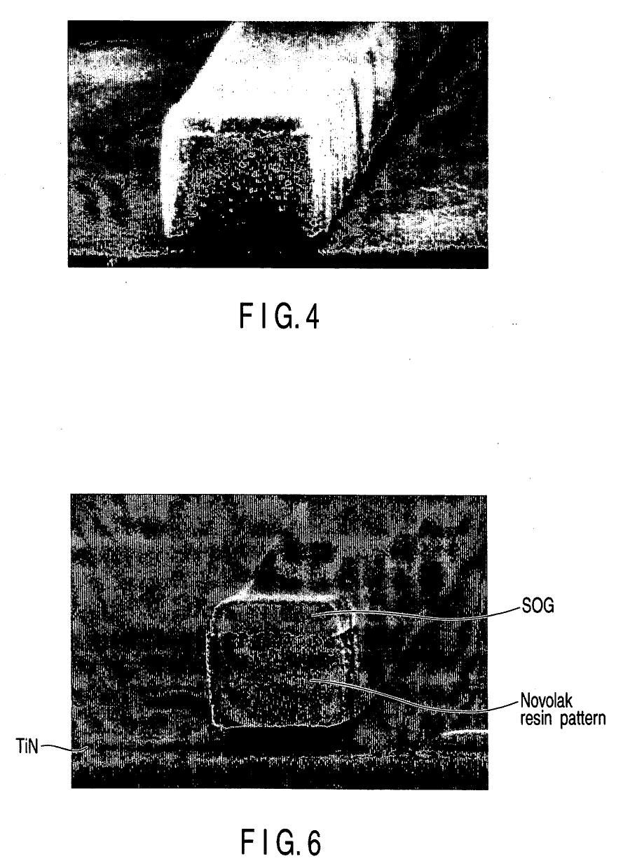

The state of the wiring material film (the TiN film of the second conductive barrier film) having a two-layer pattern comprising the patterns of the SOG film and novolac resin film was observed by means of an electron microscope immediately after the H₂ plasma treatment in Example 2. AS shown in the SEM photograph in FIG. 4, whiskers of the corroded layer were not formed at all at the TiN film of the second conductive barrier film located in the vicinity of the wall of the two-layer pattern. No side etching was observed in the pattern of the novolac resin film.

Since whiskers of the corroded layer were not observed at all, the wiring formed in Example 2 had a width that precisely reflects the width of the originally formed resist pattern.

### EXAMPLE 3

FIG. 5 is a schematic cross section showing a plasma etching apparatus, e.g., an RIE apparatus of a parallel plate type for use in forming the pattern of the organic material film (the pattern of the novolac resin) in Example 3.

An exhaust pipe 23 is connected to the bottom of a treatment vessel 22 having a vacuum chamber 21. An evacuation apparatus such as a vacuum pump (not shown) is connected to the exhaust pipe 23. A lower plate electrode 24 and an upper plate electrode 25 are disposed in the chamber 21 so as to parallel each other. The lower plate electrode 24 is supported by a first support member 26 that is inserted by penetrating through the bottom of the treatment vessel 22. The first support member 26 and the treatment vessel 22 are grounded. The upper plate electrode 25 is supported by a second support member 27 that is inserted by penetrating through the top of the treatment vessel 22. The second support member 25 is insulated at the insertion part through the treatment vessel 22, and is connected to a high frequency power source 28 operated at a frequency of 100 MHz. The lower end of a gas inlet pipe 29 for introducing oxygen gas penetrates through the top of the treatment vessel 22, and is inserted into and fixed at the center of the top plate electrode 25 to introduce oxygen gas from the lower end of the pipe toward the lower plate electrode 24.

The following treatments were applied according to the same method as in Example 1. An interlayer dielectric film was deposited on the surface of the silicon substrate, and a wiring material film having a three-layer structure (substantially five-layer structure) comprising a first conductive barrier film of titanium/titanium nitride, an Al—Si—Cu alloy film (an Al alloy film) and a second conductive barrier film of titanium/titanium nitride was formed on the surface of the interlayer dielectric film. Subsequently, a novolac resin film (trade name PER IX370G, manufactured by LSR Co.) as an organic material film with a thickness of 300 nm and a SOG film with a thickness of 80 nm were formed on the surface of the second conductive barrier film of the wiring material film by a spin-coat method. Then, after forming a chemical amplification resist pattern on the surface of the SOG film, the pattern of the SOG film was formed by RIE processing of the SOG film using the resist pattern as a mask.

Next, the silicon substrate 1 having the pattern of the SOG film was transferred onto the lower plate electrode 24 in the vacuum chamber 21 of the RIE apparatus shown in FIG. 5. A process gas O₂ was introduced from the gas inlet pipe 29 into the chamber 21 region between the upper and lower plate electrodes 24 and 25 at a flow speed of 150 sccm while evacuating the gas in the chamber 21 through the exhaust pipe 23 by operating a vacuum pump (not shown) to adjust the gas pressure in the vacuum chamber 21 to 1 Pa. Subsequently, oxygen plasma was generated between the upper and lower plate electrodes 24 and 25 by applying an RF output of 2000 W at a frequency of 100 MHz on the upper plate electrode 25 from the high frequency power source 28. The novolac resin film was processed by RIE using the pattern of the SOG film as a mask to thereby form the pattern of the novolac film.

Subsequently, the silicon substrate having the two-layer pattern comprising the patterns of the SOG film and novolac resin film was taken out of the chamber of the RIE apparatus shown in FIG. 5 into air. Thereafter, the substrate was transferred onto the lower electrode in the chamber of the RIE apparatus of the IPC type as in Example 1. A wiring of the stacked structure comprising a first conductive barrier film, an Al alloy film and a second conductive barrier film on the surface of the interlayer dielectric film was formed by sequentially processing the second conductive barrier film, the Al alloy film and the first conductive barrier film of the wiring material film by RIE using the two-layer pattern comprising the patterns of the SOG film and novolac resin film as a mask. The semiconductor device was manufactured through the process described above.

The state of the wiring material film (the TiN film of the second conductive barrier film) comprising the patterns of the SOG film and novolac resin film was observed by means of an electron microscope immediately after the RIE processing of the novolac resin film with oxygen plasma in Example 3.

As shown in the SEM photograph in FIG. 6, no side etching was observed in the pattern of the novolac resin film with a shape that precisely reflects the pattern of the SOG film. Whiskers of the corroded layer were also not observed at all at the second conductive barrier film located in the vicinity of the wall portion of the two-layer pattern.

Accordingly, the wiring formed in Example 3 had a width that precisely reflects the width of the originally formed resist pattern.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method for manufacturing a semiconductor device, comprising:
forming a wiring material film of a stacked structure by depositing a first conductive barrier film, an aluminum film or an aluminum alloy film, and a second conductive barrier film on a semiconductor substrate in this order;
forming an organic material film, a silicon oxide film and a resist film on the surface of the second barrier film in this order;
forming a resist pattern on the surface of the silicon oxide film by patterning the resist film by lithography;
forming a pattern of the silicon oxide film on the surface of the organic material film by etching the silicon oxide film with a process gas containing at least fluorine using the resist pattern as a mask;
treating the substrate with a plasma of a process gas containing C, a process gas containing H or a process gas containing O before exposing the substrate to air after forming the pattern of the organic material film on the surface of the conductive barrier film by etching the organic material film with a process gas containing H and N using the pattern of the silicon oxide film as a mask; and
forming a wiring by etching the wiring material film using the patterns of the silicon oxide film and organic material film as masks.

2. The method for manufacturing a semiconductor device according to claim 1, wherein each of the first and second conductive barrier films comprises at least one film selected from Ti, TiN, Ta, TaN, W and WN films.

3. The method for manufacturing a semiconductor device according to claim 1, wherein the silicon oxide film is a spin-on-glass film having a thickness of 30 to 80 nm.

4. The method for manufacturing a semiconductor device according to claim 1, wherein the process gas containing fluorine is a CHF₃/O₂ gas, CF4/O₂ gas C₄F₈/O₂ gas, CH₃F/Ar gas, CF4/Ar gas or C₄F₄/Ar/O₂ gas.

5. The method for manufacturing a semiconductor device according to claim 1, wherein the process gas containing H and N is a N₂/H₂ gas.

6. The method for manufacturing a semiconductor device according to claim 1, wherein the process gas containing H and N further contains O.

7. The method for manufacturing a semiconductor device according to claim 6, wherein the process gas containing N and O is a NH₃/O₂ gas or a N₂/CH₄/O₂ gas.

8. The method for manufacturing a semiconductor device according to claim 7, wherein the O₂ concentration of the process gas containing N and O is 10% or less.

9. The method for manufacturing a semiconductor device according to claim 1, wherein the process gas containing C for use in the plasma treatment is a saturated hydrocarbon gas selected from CH₄, C₂H₆ and C₃Hg gases or CO, the process gas containing H is hydrogen, and the process gas containing O is oxygen or CO₂.

10. The method for manufacturing a semiconductor device according to claim 1, wherein reactive ion etching is used for etching of the silicon oxide film with the process gas containing fluorine, etching of the organic material film with the process gas containing H and N, and etching of the wiring material film.

11. A method for manufacturing a semiconductor device, comprising:
forming a wiring material film of a stacked structure by depositing a first conductive barrier film, an aluminum film or an aluminum alloy film and a second conductive barrier film on a semiconductor substrate in this order;
forming an organic material film, a silicon oxide film and a resist film on the surface of the second conductive barrier film in this order;
forming a resist pattern on the surface of the silicon oxide film by patterning the resist film by lithography;
forming a pattern of the silicon oxide film on the surface of the organic material film by etching the silicon oxide film with a process gas containing at least fluorine using the resist pattern as a mask;
providing a plasma etching apparatus comprising a vacuum chamber and two plate electrodes arranged in the vacuum chamber so as to parallel each other;
holding the semiconductor substrate having the pattern of the silicon oxide film on one plate electrode in the vacuum chamber of the plasma etching apparatus;
introducing a process gas containing O in the vacuum chamber;
adjusting the pressure in the chamber to 1 Pa or less;
generating an oxygen plasma in the chamber by applying a high frequency power to the other plate electrode to selectively etch the organic material film using the pattern of the silicon oxide film as a mask, thereby forming a pattern of the organic material film on the surface of the conductive barrier film; and
forming a wiring by etching the wiring material film using the patterns of the silicon oxide film and organic material film as masks.

12. The method for manufacturing a semiconductor device according to claim 11, wherein each of the first and second conductive barrier films comprises at least one film selected from Ti, TiN, Ta, TaN, W and WN films.

13. The method for manufacturing a semiconductor device according to claim 11, wherein the silicon oxide film is a spin-on-glass film having a thickness of 30 to 80 nm.

14. The method for manufacturing a semiconductor device according to claim 11, wherein the process gas containing fluorine is a CHF₃/O₂ gas, CF₄/O₂ gas, C₄F₈/O₂ gas, CH₃F/Ar gas, CF₄/Ar gas or C₄F₄/Ar/O₂ gas.

15. The method for manufacturing a semiconductor device according to claim 11, wherein the process gas containing O is oxygen.

16. The method for manufacturing a semiconductor device according to claim 11, wherein the pressure in the chamber is 0.5 to 1 Pa.

17. The method for manufacturing a semiconductor device according to claim 11, wherein the high frequency power applied to the other plate electrode has a frequency of 100 MHz.

18. The method for manufacturing a semiconductor device according to claim 11, wherein reactive ion etching is used for etching of the silicon oxide film 25 with the process gas containing fluorine and etching of the wiring material film.
